(19) United States
(12) Patent Application Publication
(10) Pub. No.: US 2008/0245300 A1
(43) Pub. Date: Oct. 9, 2008

(54) APPARATUS AND METHOD FOR CONTINUOUSLY COATING STRIP SUBSTRATES

(75) Inventor: STEPHAN KUPER, BAD HOMBURG (DE)

Correspondence Address: CANTOR COLBURN, LLP, 20 Church Street, 22nd Floor, Hartford, CT, 06103, US

(73) Assignee: LEYBOLD OPTICS GMBH, ALZENAU (DE)

(21) Appl. No.: 11/947,475

(22) Filed: Nov. 29, 2007

Related U.S. Application Data
(60) Provisional application No. 60/872,757, filed on Dec. 4, 2006.

(51) Int. Cl. C23C 16/06

(52) U.S. Cl. 118/724

(57) ABSTRACT

A device and a method for coating of a sheet-like substrate that can be moved with respect to an evaporator bench in a running direction, whereby the evaporator bench has a number of heatable evaporator boats arranged directly adjacent to each other in the evaporator bench and their longitudinal axes enclose an angle with respect to the running direction, whose absolute value lies between 1° and 89°, and whereby the device has an arrangement for supplying wire of a material being evaporated to the evaporator boats, where the evaporator boats are arranged alternating next to each other, so that an evaporator boat, whose longitudinal axis is rotated counterclockwise with respect to the running direction is situated next to an evaporator boat, whose longitudinal axis is rotated clockwise with respect to the running direction.

The invention relates to a device and method according to the preambles of the independent claims.

The use of coating sources that form an evaporator bench is known from metal coating of sheet-like substrates. The coating sources often have an elongated shape and are then referred to as evaporator boats. The evaporating material, preferably aluminum, forms a vapor lobe with a characteristic intensity distribution or emission characteristic of the evaporated material over the individual evaporator boats. In typical devices for sheet coating, the sheet-like substrate is unwound from a feed roller and fed to a take-up roller and then moved in the area above the evaporator bench, so that the downward-facing side of the substrate is coated with metal evaporated in the evaporator boats.

A special device for continuous coating of sheet-like substrates is known from DE 40 27 034 C1 and EP 074,964 B1. According to them, a number of evaporator boats of roughly the same size and configuration arranged parallel and at roughly equal spacings to each other along the bench running direction, forming an evaporator bench, are provided. The evaporator boats are all formed from an electrically conducting ceramic and can be heated by direct-current passage. A device for continuous feed of wire to be evaporated to the evaporator boats is also provided. The individual evaporator boats lying parallel to each other or to the sheet-running direction of the evaporator bench are arranged offset with respect to one another, whereby all the evaporator boats together cover a narrow coating zone that extends across the running direction of the sheet.

It is known, among other things, from documents DE 40 27 034 C1 and EP 074,964 B1, that a non-uniform layer distribution on the sheet being coated is formed by overlapping of the vapor lobes. In the ideal case, this is a wave-like distribution with maxima and minima above or between the evaporator boats. The layer uniformity achievable in the best case is determined by the amplitude of the maxima and minima, the amplitude being dependent on the geometric arrangement and emission characteristics of the individual evaporator boats and on the interaction of the vapor lobes of the evaporator boats with one another. To improve layer-thickness uniformity in individual evaporator boats of the evaporator bench arranged parallel to on another, it is proposed in the documents cited to arrange the evaporator boats offset relative to one another, so that together they cover a narrow coating zone. However, a loss of efficiency during coating then occurs.

A coating device with several evaporator boats directly adjacent to each other is also known from EP 1,408,135 A1, the boats being arranged at an angle with respect to the running direction of the substrate. In order to achieve improved layer uniformity, several evaporation baths are seen in each boat, so that higher coating quality should be produced.

The present invention is based on the task of devising another and better possibility of achieving higher coating quality during coating of a sheet-like substrate by means of evaporator boats forming an evaporator bench.

The task mentioned is solved according to the invention by the features of the independent claims.

It is proposed according to the invention that the evaporator bench be formed by a set A and a set B of evaporator boats. During coating, the sheet-like substrate can be moved in a running direction X perpendicular to a direction Y. The set A of evaporator boats has a length LA in a range between L0−δA and L0+δA, whereas the evaporator boats of set B have a length LB and a range between L0−δB and L0+δB. The evaporator boats of set A and set B are arranged within a zone extending parallel to the Y direction with a width in the X direction of at most 2 L0+δA+δB.

The evaporator boats of set A are each arranged at an angle α in a range between −1° and −89° with respect to direction X, the angle being oriented clockwise. The evaporator boats of set B are each arranged at an angle β in a range between 1° and 89° with respect to direction X, the angle being oriented clockwise. The evaporator boats of set A and set B are arranged alternating next to each other and form a herringbone pattern. The evaporator boats of set A and set B therefore each have a deviation from parallelism to running direction X. The evaporator boats of set A are also rotated with respect to the evaporator boats of set B.

With these deliberate deviations from parallelism of the evaporator boats with respect to running direction X, as well as their mutual orientation, a higher layer uniformity can surprisingly be achieved than with evaporator boats that are arranged parallel to the running direction X and parallel to one an other. Simulation calculations were performed to understand these results. It was assumed in the simulation calculations that the vapor lobe of an individual evaporator boat has a Gaussian or cosⁿ intensity distribution across the longitudinal axis of an evaporator boat. This type of intensity distribution was described, for example, in the article by Susaki and Ikarashi (AIMCAL Fall Technical Conference, Reno, Oct. 22, 2007, Vacuum Webcoating Sessions, Session 2 B, FIG. 8).

In a Gaussian or cosⁿ intensity distribution, the vapor lobes have arms. With a number of evaporator boats, interaction of the vapor lobes is assumed, to the extent that the intensity distribution becomes narrower and sharper, the more the vapor lobes interact with one another. In an arrangement of boats parallel to the sheet-running direction, the arms of the vapor lobes point toward the center of greatest intensity of the next boat of subset A or B. This should lead to a concentration of the distribution. During rotation of the evaporator boats according to the invention, one arm points outward, whereas the other arm points between the density centers of the adjacent boats. In both cases, lower interaction of the vapor lobes is expected. Based on simulation calculations, it is suspected that the reduction in layer-thickness fluctuation is due to the fact that the variation of intensity distribution of the overlapping vapor lobes of the evaporator boats arranged in the evaporator bench becomes lower, since the intensity distribution of the individual boats has become wider overall.

The preferred values of angles α and β depend on the geometric arrangement of the evaporator boats, as well as the shape of the vapor lobe, i.e., the characteristic intensity distribution over the evaporator boats.

In a particularly simple variant, the angles of all evaporator boats of sets A and/or B are equally large.

In modifications of the invention, angle α lies in a range between −5 and 15° and/or angle β lies in a range between 5° and 15°.

It has also been found that it is advantageous if the sum of angles α and β equals 0°.

Design advantages are gained if the evaporator boats of set A have length L0 and/or the evaporator boats of set B have length L0.

In another variant of the invention, the evaporator boats of set A are arranged in a strip SA and/or the evaporator boats of set B are arranged in a strip SB, strips SA and SB having an overlapping zone Z. The evaporator boats of set A and/or set B are therefore geometrically combined, so that the choice of appropriate values for angles α and β is facilitated. Strips SA and SB could each have constant widths BA and BB. Strips SA and SB can favorably have the same width. It is particularly favorable, if strips SA and SB are each arranged parallel to direction Y, i.e., perpendicular to running direction X.

The [width of the] overlapping zone Z can be smaller than or equal to the width of the narrowest of these strips SA and SB.

In a preferred variant, all evaporator boats have length L0, the angle of the evaporator boats of set A equals α, the angle of the evaporator boats of set B equals β, and strips SA and SB have the same constant width B. Strips SA and SB can be also be arranged parallel to the Y direction. In this case, geometric points of the same type of the evaporator boats of set A each lie on a straight line parallel to direction Y, whereas the geometric points of the same type of evaporator boats of set B are arranged on a straight line shifted parallel to this line. Geometric points of the same type include corner points or center points of the evaporator boats. An overlapping zone Z with width BZ and a range between 0.1 B and 0.95 B is preferred, with particular preference between 0.6 B and 0.8 B. A further reduction in layer-thickness fluctuation can be achieved thereby.

The evaporator boats of set A and/or set B preferably have the same spacing from one another, with respect to the geometric points of the same type of evaporator boats. It is understood that different spacings can also be provided.

Optimal values can be chosen according to the invention for angles α and β, so that the value of layer-thickness fluctuation (Dmax−Dmin):(Dmax+Dmin) is minimal.

The task is also solved by a method for laying out a device for coating a sheet-like substrate, in which the substrate can be moved during coating in a running direction X perpendicular to a direction Y, with a number of evaporator boats that form an evaporator bench, the number of evaporator boats being formed by a set A and a set B of evaporator boats, the evaporator boats of set A having a length LA in a range between L0−δA and L0+δA, the evaporator boats of set B having a length LB in a range between L0−δB and L0+δB, and the number of evaporator boats within an area extending parallel to direction Y with a width of, at most, 2 L0+δA+δB being arranged in the X direction. It is then proposed that the evaporator boats of set A and set B be arranged alternating next to each other and the evaporator boats of set A be each arranged at an angle β in a range between −1° and −89° with respect to direction X and the evaporator boats of set B be each arranged at angle β between 1° and 89° with respect to direction X.

Additional advantageous variants of the invention can also be seen independently from their summary in the claims and the following drawings, as well as the corresponding description.

In the drawings:

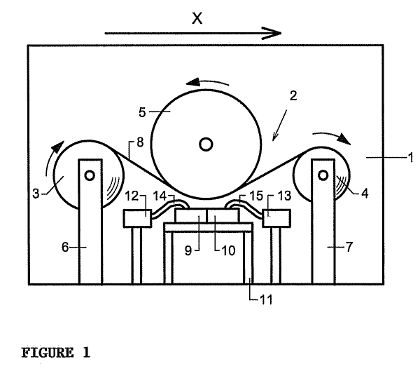

FIG. 1 shows a schematic representation of a device for coating of a sheet-like substrate

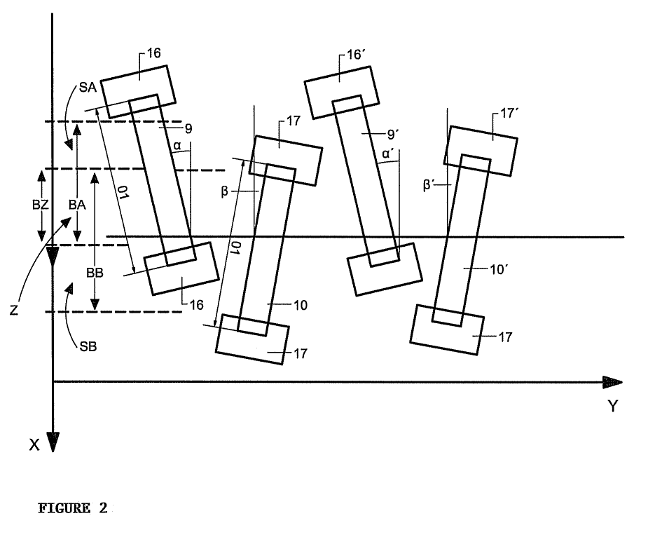

FIG. 2 shows a schematic view of an arrangement according to the invention of evaporator boats, in a top view

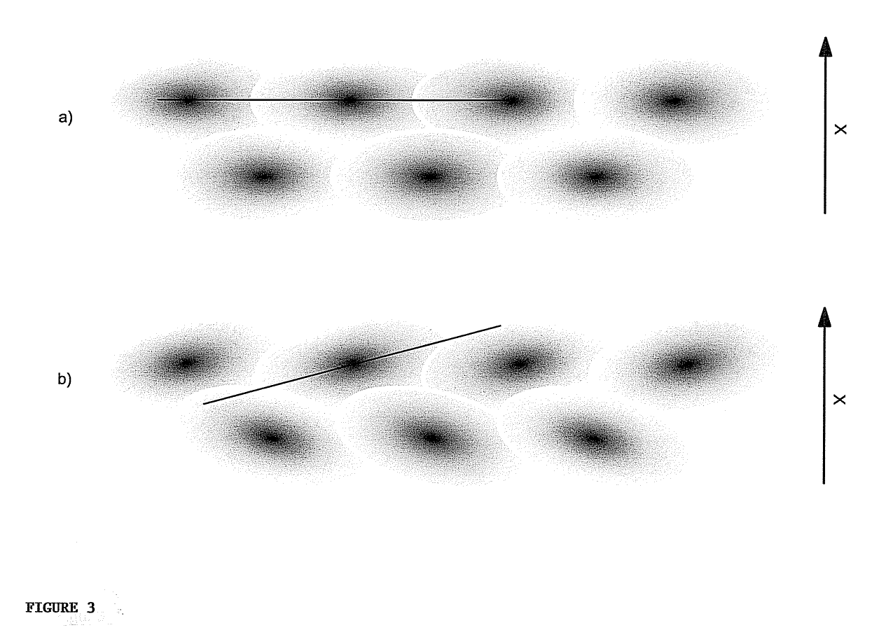

FIG. 3 shows a schematic view of vapor lobes of evaporator boats

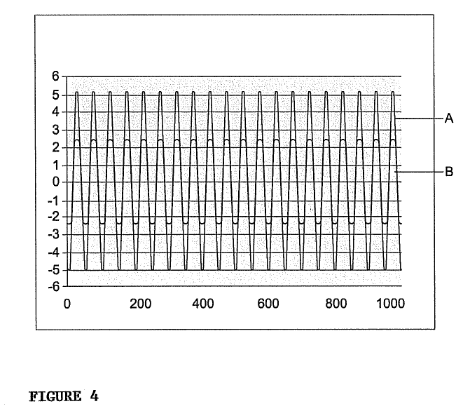

FIG. 4 shows the results of a simulation calculation of layer-thickness changes or evaporator boats arranged according to the invention, offset and parallel.

A schematic side view of the vacuum chamber 1 with a coating installation 2 is shown in FIG. 1. The coating installation has a feed roller 3, a take-up roller 4, and a coating drum 5. The feed roller and take-up roller 3 and 4 are mounted on supports 6, 7. The corresponding support for the coating drum 5 is not shown in FIG. 1. The feed roller 3 is formed by a wound sheet-like substrate 8, for example, a film. The substrate 8 is unwound in running direction X to the take-up roller 4 and guided by the coating drum 5. Beneath the coating drum 5, evaporator boats 9, 10 are shown, which are arranged on a table 11. Devices 12, 13, which guide wires of a material 14, 15 being evaporated into the area of the evaporator boats 9, 10 are shown next to the evaporator boats 9, 10. The evaporator boats 9, 10 are heated by means of a heating device (not shown), so that the wires evaporate in or on the evaporator boats 9, 10. The evaporated material is deposited on the downward-directed side of film 8.

The evaporator boats 9, 10 preferably have a rectangular shape, preferably consist of temperature-resistant ceramic, and can have a recess, referred to as a cavity, on their surface. Evaporator boats without a cavity are also known. The surface can also additionally have fluting or other structures. Aluminum, in particular, is considered as the material of the wires being evaporated.

Rectangular evaporator boats 9, 9′ and 10, 10′ are shown in a top view in FIG. 2, which form part of an evaporator bench. The evaporator boats 9, 9′, 10, 10′ are arranged by means of fastening parts 16, 16′, 17, 17′ in stipulated positions relative to running direction X and perpendicular to direction X. The evaporator boats 9, 9′ and 10, 10′ in FIG. 2 all have the same length L0. Evaporator boats 9 and 9′ are each arranged at an angle α or α′ in a range between −1° and −89° to direction X. Evaporator boats 10 and 10′ are arranged at an angle β or β′ and arranged between 1° and 89° to direction X. Graphically speaking, the evaporator boats in FIG. 2 form a herringbone pattern.

Whereas only four evaporator boats are shown in the depiction of FIG. 2, it is understood that the invention includes 8 evaporator benches with a number of evaporator boats.

The length of the evaporator boats can also be different.

According to the invention, the evaporator boats form a set A and a set B, the elements of set A having a length LA in a range between L0−δA and L0+δA and the elements of set P [should be: B] having a length LB in the range between L0−δB and L0+δB. The boats of set A have an angle α between −1° and −89° with respect to the Y direction, the evaporator boats of set B an angle β in a range between 1° and 89°. The evaporator boats of sets A and B are arranged in an area with a maximum width of 2 L0+δA+δB. FIG. 2 corresponds to the situation with δA=δB=0.

The arrangement of the evaporator boats according to the invention in a herringbone pattern permits a reduction in the layer-thickness fluctuation (Dmax−Dmin):(Dmax+Dmin) with respect to known arrangements of the evaporator boats, whereby Dmax denotes the maximum and Dmin the minimum layer thickness of a coated substrate.

FIG. 3 compares the intensity distribution of evaporated material in an area above a conventional arrangement of evaporator boats (FIG. 3a) and an arrangement of evaporator boats according to the invention (FIG. 3b). The evaporator boats are each rectangular with a longitudinal axis. FIG. 3a corresponds to rectangular evaporator boats offset with respect to each other, arranged parallel to each other and to the running direction X of a substrate. FIG. 3b corresponds to an arrangement of evaporator boats that are arranged at an angle of −5° or 5° to running direction X. A Gaussian or cosⁿ intensity distribution or vapor lobe with maxima essentially perpendicular to the longitudinal axis of the evaporator boats was then assumed for the individual evaporator boats. For simplification, in the representation of FIG. 3, only the intensity distribution pertaining to one evaporator boat is shown in the overlapping areas of the vapor lobes. The line shown in FIG. 3a between the centers of three vapor lobes illustrates that areas with high intensity overlap. It is can be seen in FIG. 3b that in the inner area of the distribution, overlapping of areas with lower intensity occurs and in the outer area, areas free of overlapping occur, so that the distribution overall is broader than in the case of FIG. 3a. Simulation shows that even slight changes in the width of the distributions can cause significant changes in layer-thickness fluctuation.

The resulting layer-thickness fluctuations were calculated in simulation calculations for the arrangements in evaporator boats corresponding to FIGS. 3a and 3b. FIG. 4 shows the results of simulation calculations in which curve A corresponds to the arrangement of FIG. 3a and curve B to the arrangement of FIG. 3b, each with 22 geometrically identical evaporator boats, i.e., of the same length and shape. A Gaussian shape was chosen for the intensity distribution. The abscissa then corresponds to a position perpendicular to the running direction X, the ordinate gives the layer-thickness fluctuation in percent. During the simulation calculation, the parameters for the arrangement according to FIG. 3a were chosen, so that a layer-thickness fluctuation of ±5% about an average resulted.

As shown in FIG. 4, in an arrangement according to the invention with the same parameters as those of the conventional arrangement of FIG. 3a, but with evaporator boats rotated by −5° or 5° to the running direction X, a layer-thickness fluctuation of only ±2.5% was found. Similar improvements were obtained in a cosⁿ-like intensity distribution and in real coating experiments.

The invention relates to a device and method according to the preambles of the independent claims.

The use of coating sources that form an evaporator bench is known from metal coating of sheet-like substrates. The coating sources often have an elongated shape and are then referred to as evaporator boats. The evaporating material, preferably aluminum, forms a vapor lobe with a characteristic intensity distribution or emission characteristic of the evaporated material over the individual evaporator boats. In typical devices for sheet coating, the sheet-like substrate is unwound from a feed roller and fed to a take-up roller and then moved in the area above the evaporator bench, so that the downward-facing side of the substrate is coated with metal evaporated in the evaporator boats.

A special device for continuous coating of sheet-like substrates is known from DE 40 27 034 C1 and EP 074,964 B1. According to them, a number of evaporator boats of roughly the same size and configuration arranged parallel and at roughly equal spacings to each other along the bench running direction, forming an evaporator bench, are provided. The evaporator boats are all formed from an electrically conducting ceramic and can be heated by direct-current passage. A device for continuous feed of wire to be evaporated to the evaporator boats is also provided. The individual evaporator boats lying parallel to each other or to the sheet-running direction of the evaporator bench are arranged offset with respect to one another, whereby all the evaporator boats together cover a narrow coating zone that extends across the running direction of the sheet.

It is known, among other things, from documents DE 40 27 034 C1 and EP 074,964 B1, that a non-uniform layer distribution on the sheet being coated is formed by overlapping of the vapor lobes. In the ideal case, this is a wave-like distribution with maxima and minima above or between the evaporator boats. The layer uniformity achievable in the best case is determined by the amplitude of the maxima and minima, the amplitude being dependent on the geometric arrangement and emission characteristics of the individual evaporator boats and on the interaction of the vapor lobes of the evaporator boats with one another. To improve layer-thickness uniformity in individual evaporator boats of the evaporator bench arranged parallel to on another, it is proposed in the documents cited to arrange the evaporator boats offset relative to one another, so that together they cover a narrow coating zone. However, a loss of efficiency during coating then occurs.

A coating device with several evaporator boats directly adjacent to each other is also known from EP 1,408,135 A1, the boats being arranged at an angle with respect to the running direction of the substrate. In order to achieve improved layer uniformity, several evaporation baths are seen in each boat, so that higher coating quality should be produced.

The present invention is based on the task of devising another and better possibility of achieving higher coating quality during coating of a sheet-like substrate by means of evaporator boats forming an evaporator bench.

The task mentioned is solved according to the invention by the features of the independent claims.

It is proposed according to the invention that the evaporator bench be formed by a set A and a set B of evaporator boats. During coating, the sheet-like substrate can be moved in a running direction X perpendicular to a direction Y. The set A of evaporator boats has a length LA in a range between L0−δA and L0+δA, whereas the evaporator boats of set B have a length LB and a range between L0−δB and L0+δB. The evaporator boats of set A and set B are arranged within a zone extending parallel to the Y direction with a width in the X direction of at most 2 L0+δA+δB.

The evaporator boats of set A are each arranged at an angle α in a range between −1° and −89° with respect to direction X, the angle being oriented clockwise. The evaporator boats of set B are each arranged at an angle β in a range between 1° and 89° with respect to direction X, the angle being oriented clockwise. The evaporator boats of set A and set B are arranged alternating next to each other and form a herringbone pattern. The evaporator boats of set A and set B therefore each have a deviation from parallelism to running direction X. The evaporator boats of set A are also rotated with respect to the evaporator boats of set B.

With these deliberate deviations from parallelism of the evaporator boats with respect to running direction X, as well as their mutual orientation, a higher layer uniformity can surprisingly be achieved than with evaporator boats that are arranged parallel to the running direction X and parallel to one an other. Simulation calculations were performed to understand these results. It was assumed in the simulation calculations that the vapor lobe of an individual evaporator boat has a Gaussian or cosⁿ intensity distribution across the longitudinal axis of an evaporator boat. This type of intensity distribution was described, for example, in the article by Susaki and Ikarashi (AIMCAL Fall Technical Conference, Reno, Oct. 22, 2007, Vacuum Webcoating Sessions, Session 2 B, FIG. 8).

In a Gaussian or cosⁿ intensity distribution, the vapor lobes have arms. With a number of evaporator boats, interaction of the vapor lobes is assumed, to the extent that the intensity distribution becomes narrower and sharper, the more the vapor lobes interact with one another. In an arrangement of boats parallel to the sheet-running direction, the arms of the vapor lobes point toward the center of greatest intensity of the next boat of subset A or B. This should lead to a concentration of the distribution. During rotation of the evaporator boats according to the invention, one arm points outward, whereas the other arm points between the density centers of the adjacent boats. In both cases, lower interaction of the vapor lobes is expected. Based on simulation calculations, it is suspected that the reduction in layer-thickness fluctuation is due to the fact that the variation of intensity distribution of the overlapping vapor lobes of the evaporator boats arranged in the evaporator bench becomes lower, since the intensity distribution of the individual boats has become wider overall.

The preferred values of angles α and β depend on the geometric arrangement of the evaporator boats, as well as the shape of the vapor lobe, i.e., the characteristic intensity distribution over the evaporator boats.

In a particularly simple variant, the angles of all evaporator boats of sets A and/or B are equally large.

In modifications of the invention, angle α lies in a range between −5 and 15° and/or angle β lies in a range between 5° and 15°.

It has also been found that it is advantageous if the sum of angles α and β equals 0°.

Design advantages are gained if the evaporator boats of set A have length L0 and/or the evaporator boats of set B have length L0.

In another variant of the invention, the evaporator boats of set A are arranged in a strip SA and/or the evaporator boats of set B are arranged in a strip SB, strips SA and SB having an overlapping zone Z. The evaporator boats of set A and/or set B are therefore geometrically combined, so that the choice of appropriate values for angles α and β is facilitated. Strips SA and SB could each have constant widths BA and BB. Strips SA and SB can favorably have the same width. It is particularly favorable, if strips SA and SB are each arranged parallel to direction Y, i.e., perpendicular to running direction X.

The [width of the] overlapping zone Z can be smaller than or equal to the width of the narrowest of these strips SA and SB.

In a preferred variant, all evaporator boats have length L0, the angle of the evaporator boats of set A equals β, the angle of the evaporator boats of set B equals β, and strips SA and SB have the same constant width B. Strips SA and SB can be also be arranged parallel to the Y direction. In this case, geometric points of the same type of the evaporator boats of set A each lie on a straight line parallel to direction Y, whereas the geometric points of the same type of evaporator boats of set B are arranged on a straight line shifted parallel to this line. Geometric points of the same type include corner points or center points of the evaporator boats. An overlapping zone Z with width BZ and a range between 0.1 B and 0.95 B is preferred, with particular preference between 0.6 B and 0.8 B. A further reduction in layer-thickness fluctuation can be achieved thereby.

The evaporator boats of set A and/or set B preferably have the same spacing from one another, with respect to the geometric points of the same type of evaporator boats. It is understood that different spacings can also be provided.

Optimal values can be chosen according to the invention for angles α and β, so that the value of layer-thickness fluctuation (Dmax−Dmin):(Dmax+Dmin) is minimal.

The task is also solved by a method for laying out a device for coating a sheet-like substrate, in which the substrate can be moved during coating in a running direction X perpendicular to a direction Y, with a number of evaporator boats that form an evaporator bench, the number of evaporator boats being formed by a set A and a set B of evaporator boats, the evaporator boats of set A having a length LA in a range between L0−δA and L0+δA, the evaporator boats of set B having a length LB in a range between L0−δB and L0+δB, and the number of evaporator boats within an area extending parallel to direction Y with a width of, at most, 2 L0+δA+δB being arranged in the X direction. It is then proposed that the evaporator boats of set A and set B be arranged alternating next to each other and the evaporator boats of set A be each arranged at an angle β in a range between −1° and −89° with respect to direction X and the evaporator boats of set B be each arranged at angle β between 1° and 89° with respect to direction X.

Additional advantageous variants of the invention can also be seen independently from their summary in the claims and the following drawings, as well as the corresponding description.

In the drawings:

FIG. 1 shows a schematic representation of a device for coating of a sheet-like substrate FIG. 2 shows a schematic view of an arrangement according to the invention of evaporator boats, in a top view

FIG. 3 shows a schematic view of vapor lobes of evaporator boats

FIG. 4 shows the results of a simulation calculation of layer-thickness changes or evaporator boats arranged according to the invention, offset and parallel.

A schematic side view of the vacuum chamber 1 with a coating installation 2 is shown in FIG. 1. The coating installation has a feed roller 3, a take-up roller 4, and a coating drum 5. The feed roller and take-up roller 3 and 4 are mounted on supports 6, 7. The corresponding support for the coating drum 5 is not shown in FIG. 1. The feed roller 3 is formed by a wound sheet-like substrate 8, for example, a film. The substrate 8 is unwound in running direction X to the take-up roller 4 and guided by the coating drum 5. Beneath the coating drum 5, evaporator boats 9, 10 are shown, which are arranged on a table 11. Devices 12, 13, which guide wires of a material 14, 15 being evaporated into the area of the evaporator boats 9, 10 are shown next to the evaporator boats 9, 10. The evaporator boats 9, 10 are heated by means of a heating device (not shown), so that the wires evaporate in or on the evaporator boats 9, 10. The evaporated material is deposited on the downward-directed side of film 8.

The evaporator boats 9, 10 preferably have a rectangular shape, preferably consist of temperature-resistant ceramic, and can have a recess, referred to as a cavity, on their surface. Evaporator boats without a cavity are also known. The surface can also additionally have fluting or other structures. Aluminum, in particular, is considered as the material of the wires being evaporated.

Rectangular evaporator boats 9, 9′ and 10, 10′ are shown in a top view in FIG. 2, which form part of an evaporator bench. The evaporator boats 9, 9′, 10, 10′ are arranged by means of fastening parts 16, 16′, 17, 17′ in stipulated positions relative to running direction X and perpendicular to direction X. The evaporator boats 9, 9′ and 10, 10′ in FIG. 2 all have the same length L0. Evaporator boats 9 and 9′ are each arranged at an angle α or α′ in a range between −1° and −89° to direction X. Evaporator boats 10 and 10′ are arranged at an angle β or β′ and arranged between 1° and 89° to direction X. Graphically speaking, the evaporator boats in FIG. 2 form a herringbone pattern.

Whereas only four evaporator boats are shown in the depiction of FIG. 2, it is understood that the invention includes 8 evaporator benches with a number of evaporator boats.

The length of the evaporator boats can also be different.

According to the invention, the evaporator boats form a set A and a set B, the elements of set A having a length LA in a range between L0−δA and L0+δA and the elements of set β [should be: B] having a length LB in the range between L0−δB and L0+δB. The boats of set A have an angle α between −1° and −89° with respect to the Y direction, the evaporator boats of set B an angle β in a range between 1° and 89°. The evaporator boats of sets A and B are arranged in an area with a maximum width of 2 L0+δA+δB. FIG. 2 corresponds to the situation with δA=δB=0.

The arrangement of the evaporator boats according to the invention in a herringbone pattern permits a reduction in the layer-thickness fluctuation (Dmax−Dmin):(Dmax+Dmin) with respect to known arrangements of the evaporator boats, whereby Dmax denotes the maximum and Dmin the minimum layer thickness of a coated substrate.

FIG. 3 compares the intensity distribution of evaporated material in an area above a conventional arrangement of evaporator boats (FIG. 3a) and an arrangement of evaporator boats according to the invention (FIG. 3b). The evaporator boats are each rectangular with a longitudinal axis. FIG. 3a corresponds to rectangular evaporator boats offset with respect to each other, arranged parallel to each other and to the running direction X of a substrate. FIG. 3b corresponds to an arrangement of evaporator boats that are arranged at an angle of −5° or 5° to running direction X. A Gaussian or cosⁿ intensity distribution or vapor lobe with maxima essentially perpendicular to the longitudinal axis of the evaporator boats was then assumed for the individual evaporator boats. For simplification, in the representation of FIG. 3, only the intensity distribution pertaining to one evaporator boat is shown in the overlapping areas of the vapor lobes. The line shown in FIG. 3a between the centers of three vapor lobes illustrates that areas with high intensity overlap. It is can be seen in FIG. 3b that in the inner area of the distribution, overlapping of areas with lower intensity occurs and in the outer area, areas free of overlapping occur, so that the distribution overall is broader than in the case of FIG. 3a. Simulation shows that even slight changes in the width of the distributions can cause significant changes in layer-thickness fluctuation.

The resulting layer-thickness fluctuations were calculated in simulation calculations for the arrangements in evaporator boats corresponding to FIGS. 3a and 3b. FIG. 4 shows the results of simulation calculations in which curve A corresponds to the arrangement of FIG. 3a and curve B to the arrangement of FIG. 3b, each with 22 geometrically identical evaporator boats, i.e., of the same length and shape. A Gaussian shape was chosen for the intensity distribution. The abscissa then corresponds to a position perpendicular to the running direction X, the ordinate gives the layer-thickness fluctuation in percent. During the simulation calculation, the parameters for the arrangement according to FIG. 3a were chosen, so that a layer-thickness fluctuation of ±5% about an average resulted.

As shown in FIG. 4, in an arrangement according to the invention with the same parameters as those of the conventional arrangement of FIG. 3a, but with evaporator boats rotated by −5° or 5° to the running direction X, a layer-thickness fluctuation of only ±2.5% was found. Similar improvements were obtained in a cosⁿ-like intensity distribution and in real coating experiments.

1. A device for coating of a sheet-like substrate that can be moved with respect to an evaporator bench in a running direction,
whereby the evaporator bench has a number of heatable evaporator boats
arranged directly adjacent to each other in the evaporator bench
and their longitudinal axes enclose an angle with respect to the running direction, whose absolute value lies between 1° and 89°,
and whereby the device has an arrangement for supplying wire of a material being evaporated to the evaporator boats,
wherein the evaporator boats are arranged alternating next to each other, so that an evaporator boat, whose longitudinal axis is rotated counterclockwise with respect to the running direction is situated next to an evaporator boat, whose longitudinal axis is rotated clockwise with respect to the running direction.

2. A device according to claim 1, wherein absolute values of angles of the evaporator boats rotated counterclockwise or absolute amounts of the evaporator boats rotated counterclockwise lie in a range between 2° and 10°.

3. A device according to claim 1, wherein absolute values of the angles of all evaporator boats lie in a range between 2° and 10°.

4. A device according to claim 1, wherein the angles of the evaporator boats have roughly the same absolute value.

5. A device according to claim 4, wherein the absolute values of the angles of the evaporator boats are approximately 5°.

6. A device according to claim 1, wherein adjacent evaporator boats overlap in a running direction.

7. A device according to claim 1, wherein
the evaporator boats rotated counterclockwise are arranged within a first strip,
the evaporator boats rotated clockwise are arranged within a second strip,
and that the first and second strips have an overlapping zone.

8. A device according to claim 6, wherein each strip has a constant width.

9. A device according to claim 6, wherein the first and second strips are arranged perpendicular to running direction.

10. A device according to claim 1, wherein the angles are chosen so that the coating produced by the evaporator bench on substrate has minimal layer-thickness fluctuation.

11. A method for designing a device for a coating of a sheet-like substrates that is moved with respect to the evaporator bench in a running direction,
whereby the evaporator bench has a number of heatable evaporator boats and devices to feed wire of a material being evaporated to the evaporator boats,
whereby the evaporator boats are arranged directly adjacent to each other in the evaporator bench,
and whereby the longitudinal axes of the evaporator boats enclose an angle with respect to the running direction, whose absolute value is between 1° and 89°,
wherein the evaporator boats are arranged alternating next to one another, so that an evaporator boat whose longitudinal axis is rotated counterclockwise relative to running direction is arranged next to an evaporator boat whose longitudinal axis is rotated clockwise with respect to the running direction.

12. A method according to claim 11, wherein the angles are chosen so that the coating produced by the evaporator bench on the substrate has minimal layer-thickness fluctuation.
